(19) United States
(12) Patent Application Publication
(10) Pub. No.: US 2012/0305051 A1
(43) Pub. Date: Dec. 6, 2012

(54) FLOATING SOLAR POWER PLANT

(76) Inventors: Yuri Kokotov, Maale Adumim (IL); Yossi Fisher, Jerusalem (IL); Michael A. Reyz, Rockville, MD (US)

(21) Appl. No.: 13/578,669

(22) PCT Filed: Feb. 11, 2011
(86) PCT No.: PCT/US2011/024597

§ 371 Date: Aug. 13, 2012

Related U.S. Application Data
(60) Provisional application No. 61/304,450, filed on Feb. 14, 2010.

(51) Int. Cl. H01L 31/0203; H01L 31/0232

(52) U.S. Cl. 136/246; 136/259

(57) ABSTRACT

A floating solar power plant includes a frame floating at the surface of a water body, where the frame includes at least one cell, which is secured by at least one flexible tie to at least one floating support, which is secured to a shore of the water body by at least one suspension, with the length of each suspension selected so that the floating supports remain at the surface of the water body under all conditions of seasonal variation of water level in the water body.

### CROSS REFERENCE TO RELATED APPLICATIONS

The present Application claims the benefit of priority under 35 U.S.C. §119(e)(1) of U.S. Provisional Patent Application No. 61/304,450, titled “Floating Solar Power Plant” and filed on Feb. 14, 2010, the disclosure of which is incorporated herein by reference in its entirety.

### FIELD

The present invention relates to a solar power plant, and it can be used in solar power plants for directly converting solar energy into electric energy that can be installed as floating facilities in water bodies. More specifically, the invention can be used for building solar power plants on water bodies of irregular footprint shape, in particular, small lakes and water reservoirs as well storage ponds, clearing pools, and the like water bodies that are used for water treatment. More specifically, the invention can be used for building solar power plants on a water body with fragile bed when structural parts of the plant should be anchored to land-base structural members only and it is not allowed to use the bed of the water body for anchoring such structural members of the solar power plant.

### BACKGROUND

This section is intended to provide a background or context to the invention recited in the claims. The description herein may include concepts that could be pursued, but are not necessarily ones that have been previously conceived or pursued. Therefore, unless otherwise indicated herein, what is described in this section is not prior art to the description and claims in this application and is not admitted to be prior art by inclusion in this section.

A conventional solar power plant has a floating base platform carrying solar power modules, each module having a solar photovoltaic cell set for receiving sun radiation and for converting solar energy directly into electric energy. The base platform is floating in the water surface and is made stationary by means of flexible ties each having one end attached to the platform and the other end attached to a float, which is anchored. The floats are anchored to the water body bed. With the ties of a predetermined length, the base platform is retained in predetermined position, and it will move vertically with the water level. The base platform is caused to rotate to ensure that the sun radiation is always incident upon the photovoltaic cells. The base platform has a rotary drive mounted on the platform and a system of ropes and pulleys between the base platform and the anchoring points to ensure rotation of the platform in any direction.

One disadvantage of the conventional system is the use of an integral base platform that carries a predetermined quantity of solar modules. This system can be used for a small-size power plant, in which a platform of a certain size (10 to 15 meters in diameter) could carry 10 to 20 solar modules. With such parameters, only a small-capacity solar power plant can be built for use by a limited set of loads.

Another disadvantage is the effect of waves and wind on the system, which has special electrical control provisions to control rotational speed and/or direction in order to compensate for oscillations of the base platform. This is because the platform is a solid floating body, and it will follow the wave motions, resulting in the photovoltaic cells turning at a disadvantageous angle with respect to the sun radiation direction, and the angle of inclination of each photovoltaic cell will correspond to the angular position of the entire platform.

The circular shape of the platform does not allow it to be used for a water body of an irregular shape. In addition, if it is desired to have a power plant of a different size and/or capacity, a different platform should be built. This conventional system design is not manufacturing friendly.

Another disadvantage of the conventional system is the inclined position of the flexible ties, which creates an additional moment turning the base platform and the photovoltaic cells at a disadvantageous angle with respect to the sun radiation direction.

Accordingly, it would be desirable to provide a floating solar power plant that overcomes these and other disadvantages of conventional systems. It would also be desirable to provide a floating solar power plant, which could be used in water bodies of any configuration and size without changes in the design, by simply changing the number and arrangement of components. It would be further advantageous to provide a solar power plant in which photovoltaic cells of the solar modules retain a substantially stable angular position with respect to the solar radiation regardless of the effects of waves and wind.

### SUMMARY

According to one embodiment, a floating solar power plant includes a frame floating at the surface of a water body, where the frame includes at least one cell, which is secured by at least one flexible tie to at least one floating support, which is secured to a shore of the water body by at least one suspension, with the length of each suspension selected so that the floating supports remain at the surface of the water body under all conditions of seasonal variation of water level in the water body.

According to another embodiment, a scalable floating solar power plant for use in a water body includes a frame having a plurality of frame members defining a plurality of geometric cells arranged in a formation so that each pair of adjacent cells has a shared node. The geometric cells each including a solar power module having a circular frame that is rotatably coupled to its respective geometric cell. A plurality of buoyant supports are coupled to the frame by a plurality of flexible ties, and each of the buoyant supports has a flexible suspension configured for coupling to a bolster.

### BRIEF DESCRIPTION OF THE DRAWINGS

The disclosure will become more fully understood from the following detailed description, taken in conjunction with the accompanying figures, wherein like reference numerals refer to like elements, in which:

FIG. 1 shows a partial plan view of a solar power plant according to an exemplary embodiment of the invention.

FIG. 2 shows a detailed perspective view of a node and frame members of a solar power plant frame according to an exemplary embodiment.

FIG. 3 shows a detailed plan view of a node of a solar power plant frame according to an exemplary embodiment.

FIG. 4 shows a detailed side section of a node of a solar power plant frame according to an exemplary embodiment.

FIGS. 5a-5c show schematically various configurations of the frame of the solar power plant, showing different cell geometry according to exemplary embodiments.

FIG. 6 is a sectional view taken along line A-A in FIG. 1 according to an exemplary embodiment.

FIG. 7 shows a detailed perspective of a node and frame members of the solar power plant frame with floating pipes attached according to an exemplary embodiment.

FIG. 8 shows a partial plan view of a circular solar power module according to an exemplary embodiment.

FIG. 9 shows a sectional view taken along line B-B in FIG. 8 according to an exemplary embodiment.

FIG. 10 is a perspective view of a solar power submodule, shown from bottom up according to an exemplary embodiment.

FIG. 11 is a flexible bracket connecting the solar power submodule of FIG. 10 to the structure of the solar power module shown in FIG. 8 according to an exemplary embodiment.

FIG. 12 is a perspective view of the solar power submodule shown in FIG. 10, showing it from top.

FIG. 13 shows an alternative configuration of a pontoon shown in FIG. 12 according to an exemplary embodiment.

FIG. 14 is a plan view showing a method by which a circular frame is supported in the structure of the solar power plant and is rotated in the horizontal direction according to an exemplary embodiment.

FIG. 15 shows details of a rotary drive, a side view C in FIG. 14 according to an exemplary embodiment.

FIG. 16 shows details of rollers shown in FIG. 14 according to an exemplary embodiment.

FIG. 17 shows details of tensions mechanisms in FIG. 14 according to an exemplary embodiment.

FIG. 18 shows a side view of guiding mechanisms in FIG. 14 according to an exemplary embodiment.

FIG. 19 shows a plan view of the photovoltaic cell module of FIG. 10 from bottom up according to an exemplary embodiment.

FIG. 20 shows a plan view of an alternative embodiment of a mirror structure of FIG. 19 from bottom up.

FIG. 21 shows a side view of the mirror structure of FIG. 19, View A according to an exemplary embodiment.

FIG. 22 shows a front view of the mirror structure of FIG. 19, View B according to an exemplary embodiment.

FIG. 23 shows a front view of side mirrors of the mirror structure of FIG. 19 according to an exemplary embodiment.

### DETAILED DESCRIPTION

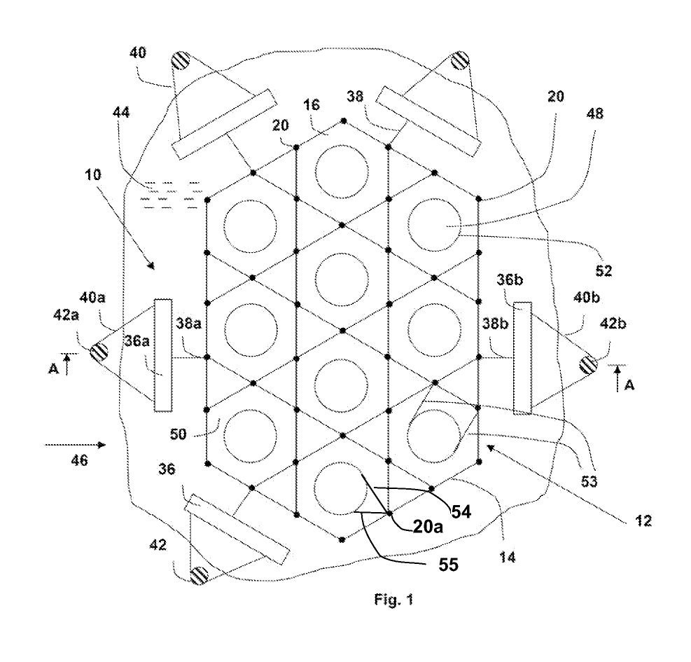

Referring to FIG. 1, a solar power plant shown generally at 10 has a frame 12, which is used for integration of the other components of the solar power plant as described below. In this embodiment, the frame 12 is shown as a structure made up of interconnected rigid frame members 14 defining substantially stiff hexagonal cells 16.

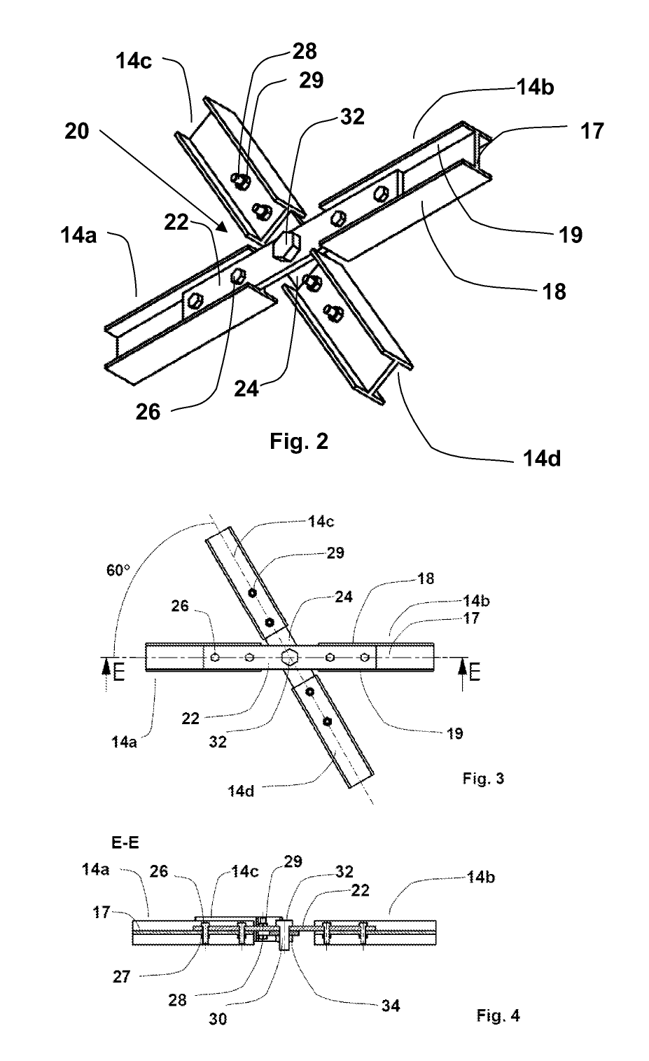

Each frame member 14 is built as an H-bar with a horizontal shelf 17 and two vertical side walls 18 and 19 as shown in FIG. 2.

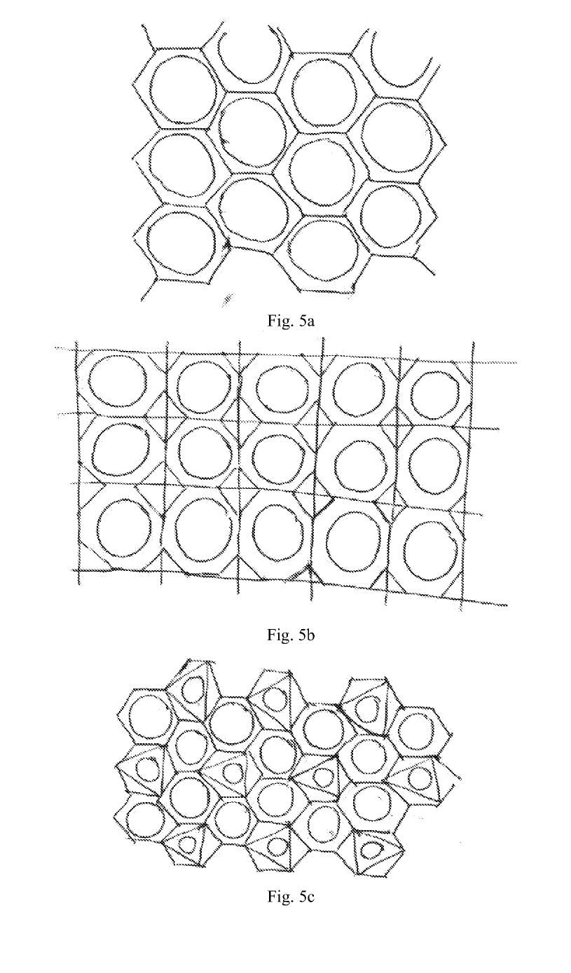

The cells 16 have nodes 20 at the points of interconnection of the frame members 14. A particular embodiment of the node 20 shown in FIGS. 2, 3 and 4 has a plate 22 and a plate 24 . The plate 22 is rigidly secured to horizontal shelves 17 of each of the two adjacent frame members 14a and 14b by a plurality of bolts 26 with nuts 27 so that the frame members 14a and 14b are directed substantially along the same straight line, and the plate 24 is rigidly secured to horizontal shelves 17 of each of the two adjacent frame members 14c and 14d by s plurality of bolts 28 with nuts 29 so that the frame members 14c and 14d are directed substantially along the same straight line. An angle formed by the straight lines formed by frame members 14a and 14b, on one side, and the straight lines formed by the frame members 14c and 14d, on the other side, is substantially close to 60°. The plate 22 with the frame members 14a and 14b rigidly secured to it via their horizontal shelves 17 and the plate 24 with the frame members 14c and 14d rigidly secured to it via their horizontal shelves 17 can rotate about an axle shown as 30 with a head 32 and a nut 34 that prevent displacement of the plates 22 and 24 relative to each other in the vertical direction. Other embodiments of the node 20 are available.

Referring again to FIG. 1, the hexagonal cells 16 are arranged in staggered configuration so that each pair of adjacent hexagonal cells has a shared node 20 and has no shared frame members 14. The frame 12 is shown in FIG. 1 as having a substantially rectangular shape, but it is understood that it can be of practically any configuration depending on the layout of the hexagonal cells 16, and the number of the cells 16 will determine the size of the frame 12.

With reference to FIG. 5, it can be seen that the configuration of the cells 16 (FIG. 1) of the frame 12 may be different as shown in FIGS. 5a, b, and c. The frame shown in FIG. 5a includes hexagonal cells where the adjacent cells share both nodes and frame members, and no additional frame members are provided within each hexagonal cell. The alternative configuration shown in FIG. 5b includes octagonal cells with square cells formed by four adjacent frame members of adjacent octagonal cells. Two additional frame members are provided within each square cell along each diagonal of this cell. It is also understood that the solar power plant 10 can be composed of cells of various shapes as shown in FIG. 5c. The frame shown in FIG. 5c consists of hexagonal cells where the adjacent cells share both nodes and frame members, and additional frame members are provided within certain hexagonal cells. These additional frame members are arranged as equilateral triangles with apexes located in the nodes of the hexagonal cells. For this configuration, each hexagonal cell, which has additional frame members within it, is surrounded in the frame by six hexagonal cells, which have additional frame members within them while each hexagonal cell, which has no additional frame members within it, is surrounded in the frame by three cells, which have additional frame members within them, and three cells, which have no additional frame members within them.

Advantageously, the cells 16 are formed as substantially stiff structures with the exception of rotation of the plate 22 with the frame members 14a and 14b rigidly secured to it and the plate 24 with the frame members 14c and 14d rigidly secured about the axle 30 at each node 20.

Referring again to FIG. 1, supports 36, which are made as buoyant bodies such as pontoons, are provided at the sides of the frame 12. The supports 36 are attached to the outboard nodes 20 of the frame 12 by flexible ties 38. Alternatively, they can be connected to the outboard frame members 14 (not shown). The supports 36 are used to secure the frame 12 by means of flexible suspensions 40 to bolsters 42, which are fixed to a secure ground, e.g., to the bank of the water body 44. The position of the supports 36 and the manner of attachment of the flexible suspensions 40 will depend on a specific configuration of the frame 12 and its cells 16.

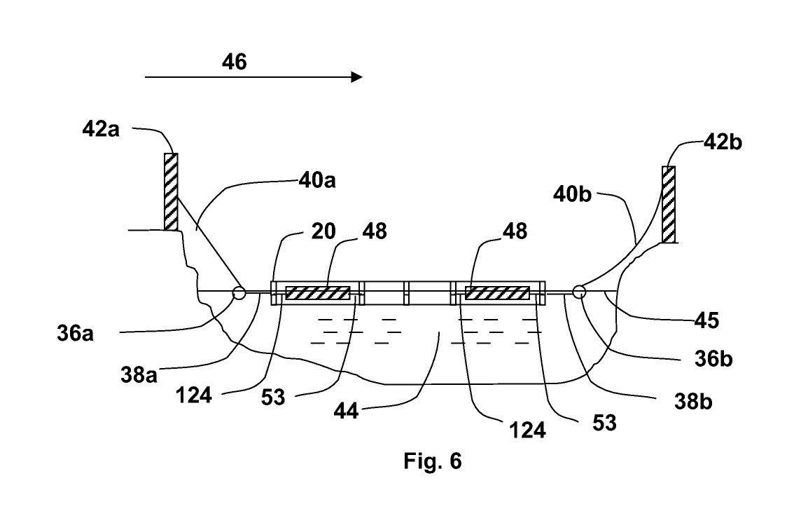

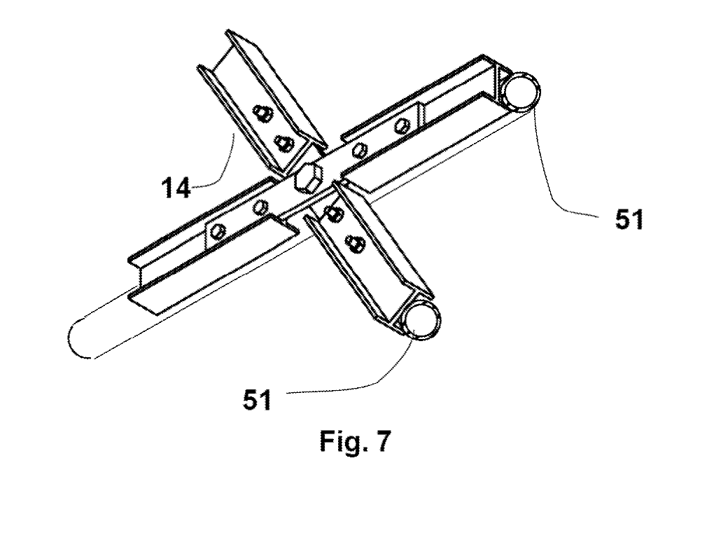

As shown in FIG. 6, under impact of wind and waves, the frame 12 and the supports 36 connected to each other by the flexible ties 38 can be displaced in a horizontal direction so that at least one flexible tie 38a and at least one flexible suspension 40a connected to the support 36a become tensioned while at least one flexible suspension 40b connected to the support 36b become slack. Advantageously, the supports 36 and the frame 12 are heavy enough to stay in floating positions at substantially the same vertical level relative to each other regardless of impact of waves and wind so that the tensioned flexible tie 38a always stays in substantially horizontal position. This is intended to eliminate undesirable moment tending to set the frame 12 and the photovoltaic cells supported by the frame 12 (not shown) at a disadvantageous angle with respect to the sun radiation direction.

Under impact of seasonal variations in the level of water in the water body 44 that occurs during operation of the solar power plant, the magnitude of displacement of the frame 12 and the supports 36 in horizontal directions varies. More specifically, this magnitude increases with increase in the level of water in the water body 44 and decreases with decrease in the level of water in the water body 44. A surface of the water body 44 is shown as 45. Advantageously, the size of the frame 12 and the lengths of the flexible ties 38 and the flexible suspensions 40 are small enough relative to the horizontal size of the water body 44 so that neither the frame 12 nor the supports 36 touch the bank of the water body 44. Such an example is shown in FIG. 6 where the support 36b remains within the perimeter of the water body 44 and does not touch its bank when the flexible suspension 40a, and both flexible ties 38a and 38b are tensioned by impact of wind blowing in the direction 46.

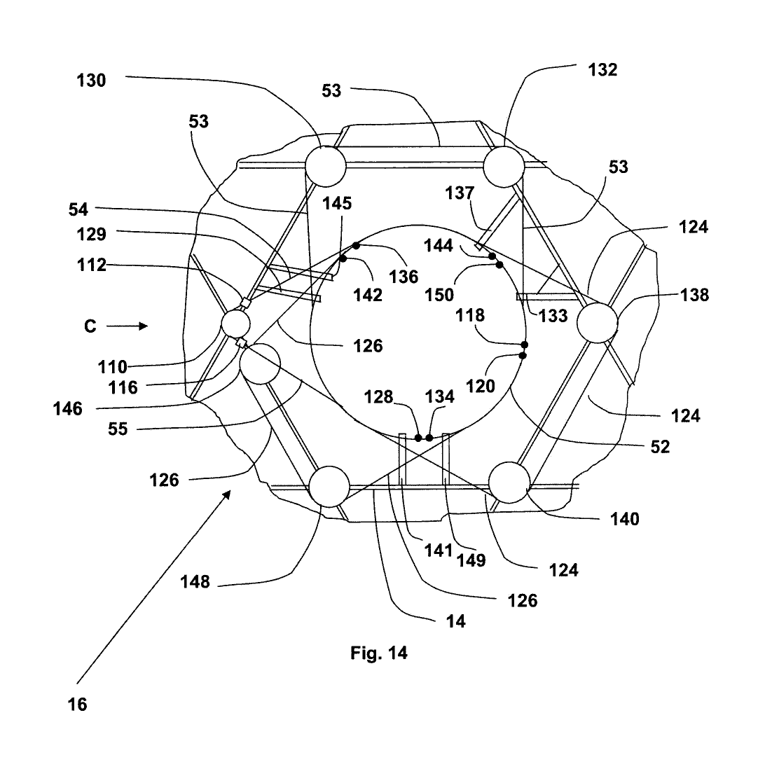

Referring again to FIG. 1, each cell 16 of the frame 12 contains a substantially circular solar power module 48 integrated in the frame 12 and described in detail below. It can be seen that, depending on the configuration of the frame 12 and the number of cells 16, any number of solar power modules can be integrated in the solar power plant. In other words, a power plant of any capacity can be built by using a standard frame 12 and standard solar power modules 48. Each solar power module 48 has a circular frame 52, which is used for integrating all components of the solar power module 48 as described below. The circular frame 52 is shown attached to two adjacent nodes 20 of the surrounding hexagonal cell 16 of the frame 12 by a pre-tensioned flexible tie 53. The circular frame 52 is attached also to the other four nodes 20 of the surrounding hexagonal cell 16 of the frame 12 by two pre-tensioned flexible ties 124 and 126 (see FIG. 14).

As shown in FIG. 7, each frame member 14 located along the same straight line is attached by clamps (not shown) to at least one flexible hollow pipe 51 sealed at both ends by plugs (not shown). The internal volume of each hollow pipe 51 is selected so that the buoyancy of the hollow pipe 51 is sufficient to ensure that the hollow pipe 51 with frame members 14 secured to it stays in floating position relative to the surface of the water body 44. According to one of available embodiments, the hollow pipe 51 is corrugated.

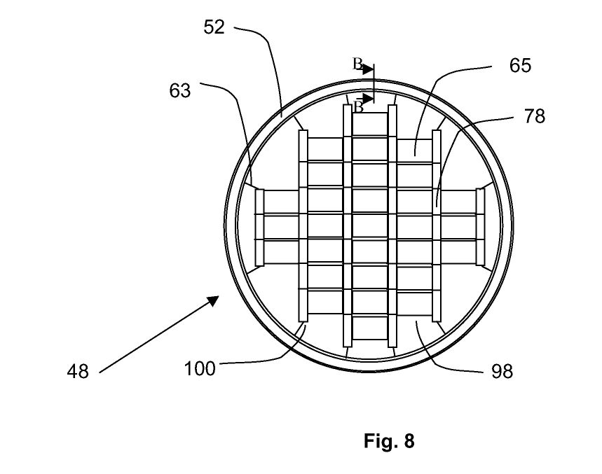

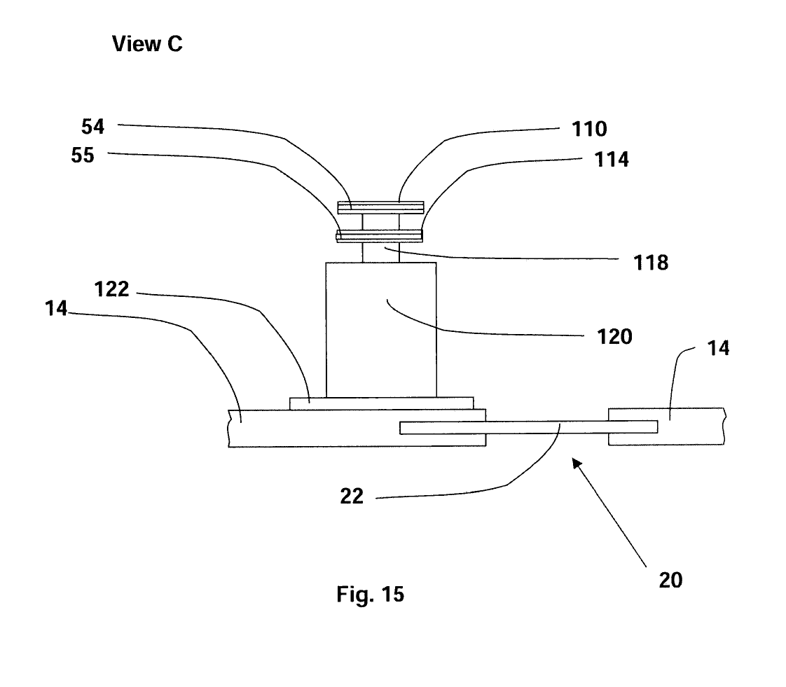

The solar power module 48, which is shown in a plan view in FIG. 8, has a circular frame 52. Referring again to FIG. 1, each circular frame 52 is secured by three flexible ties 53, and 124 and 126 (see FIG. 14), which are wrapped around the circular frame 52, to rollers 130, 132, 138, 140, 146 and 148 (see FIG. 14) located substantially at the nodes 20 of the frame 12. Each circular frame 52 is rotated by means of two driving belts 54 and 55 driven by a rotation drive mechanism (not shown) located at the node 20a of the frame 12. The details of the rotation drive mechanism are described below and shown in FIGS. 14 and 15.

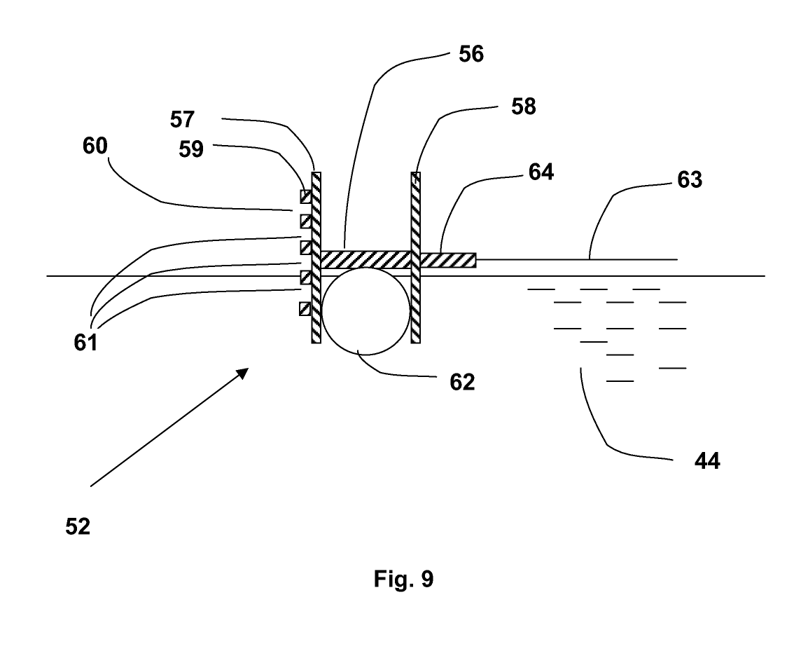

As demonstrated in FIG. 9 where a sectional view taken along line B-B in FIG. 8 is shown, the circular frame 52 is built of a circular H-bar with a horizontal shelf 56 and two vertical side walls, the outer side wall 57 oriented toward the frame members 14 that form the cell 16 surrounding the circular frame 52 (see FIG. 1) and the inner side wall 58. Five circular ribs 59 are secured to the outer surface of the outer side wall 57 of the circular frame 52 forming one circular groove 60 engaged by the driving belts 54 and 55 (see FIG. 1), and three circular grooves 61 located below the circular groove 60. Each of the circular grooves 61 is engaged by one of the three flexible ties 53, 124 or 126 (see FIG. 14). According to an alternative embodiment (not shown), the circular groove 60 engaged by the driving belts 54 and 55 is located below the circular grooves 61 engaged by the flexible ties 53. According to another alternative embodiment (not shown), the circular groove 60 engaged by the driving belts 54 and 55 is located between the circular grooves 61 engaged by the flexible ties 53, 124 or 126.

The circular frame 52 is attached by clamps (not shown) to at least one flexible hollow pipe 62 sealed at both ends by plugs (not shown). The internal volume of each hollow pipe 62 is selected so that the buoyancy of the hollow pipe 62 is sufficient to ensure that the hollow pipe 62 with the circular frame 52 secured to it stays in floating position relative to the surface of the water body 44. According to one of available embodiments, the hollow pipe 62 is corrugated.

Flexible ties 63 directed in substantially radial direction and secured to brackets 64, which are secured to the inner surface of the inner wall 58 of the circular frame 52 by clamps and bolts (not shown). The flexible ties are used for integrating solar power submodules generally shown at 65, which are made as standard components of the solar power module 48. In other words, each standard solar power module 48 is shown as composed of standard solar power submodules 65. The solar power submodules 65 are integrated within the solar power module 48 as can be better seen in and explained with reference to FIGS. 9, 10 and 11.

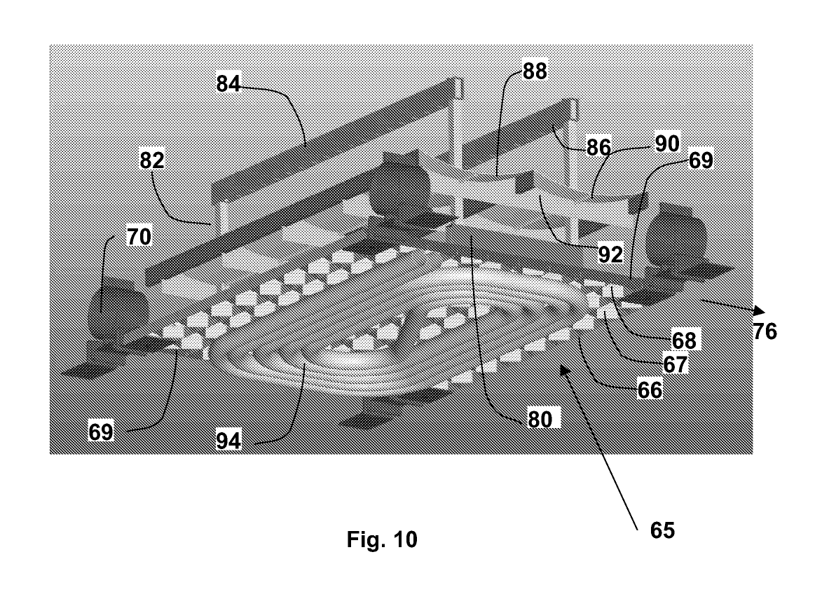

FIG. 10 shows the solar power submodule 65 in a perspective view, from bottom up. The solar power submodule 65 has a base 66 defined by a pattern of intersecting ribs 67, which extend vertically edgewise when the solar power submodule 65 is in the operational position and form base cells 68. Since the base 66 is made cellular, water can pass freely through base cells 68, and, as a result, the cells will provide a damping effect during the vertical movements of the solar power submodules 65 under the action of waves. In one embodiment, end sides 69 extending in a direction 76 are attached to the base 66.

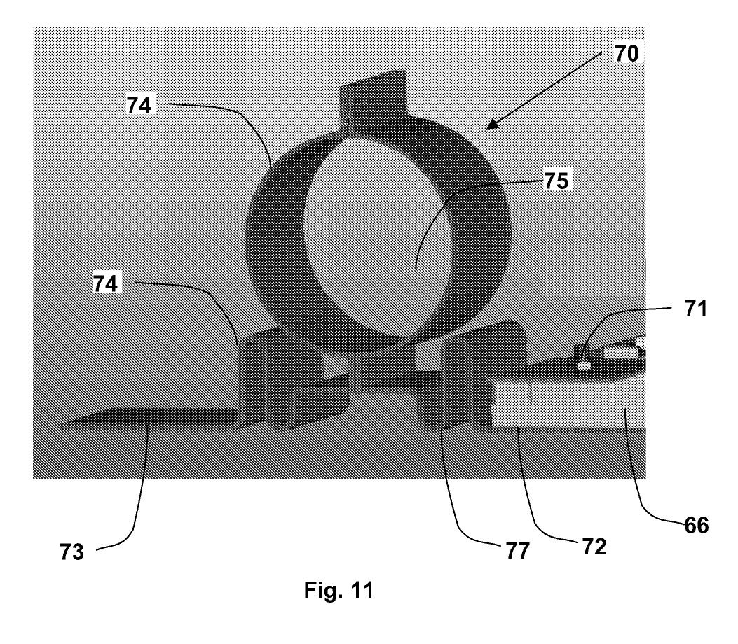

As shown in FIG. 11, flexible brackets 70 are attached to the base 66 by bolts 71 tightened against the base 66 and each bracket has two plates 72, 73 and a clamp 74, which has its opening 75 in the plane coinciding with the direction 76 in FIG. 10. The clamp 74 is shown connected to the plates 72, 73 by means of at least one flexible portion 77 in such a manner that the clamp 74 is free for a limited movement with respect to the plates 72, 73 in the plane of the opening 75. It can be seen that the openings 75 are in the planes extending at right angles with respect to the direction 76.

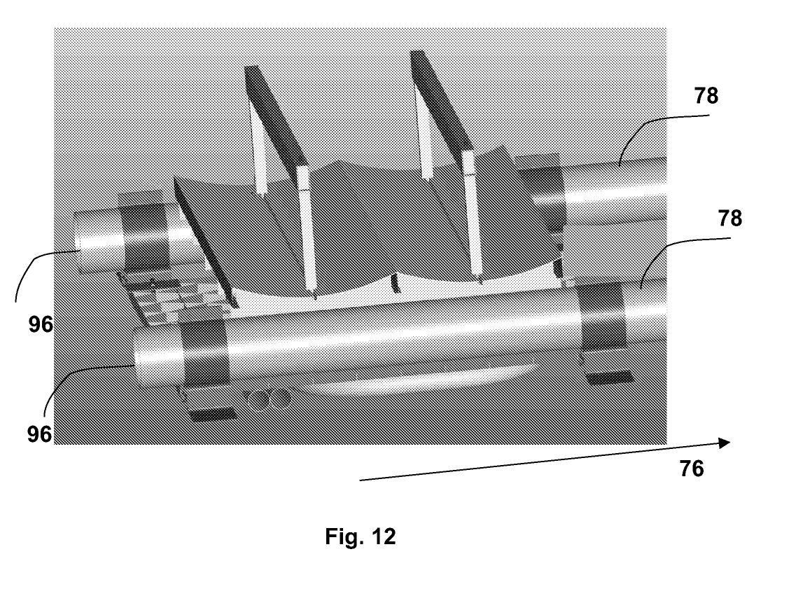

As can be seen in FIG. 12, pontoons 78, preferably of a tubular form (not necessarily cylindrical), are secured in the openings 75 (FIG. 11) of the clamps 74 of the brackets 70 of the solar power submodule 65. It is understood that the pontoons 78 extend along the direction 76, which allows the base 66 to perform a limited amount of rotation in the plane extending at right angles with respect to the pontoon axis and a limited amount of displacement in the horizontal direction orthogonal to the direction of the pontoon axis. The latter results in a limited amount of displacement of the pontoons 78 relative to each other in the horizontal direction orthogonal to the direction of their axes.

Referring again to FIG. 10, the base 66 supports at least two pedestals 80 (one of them is not shown), which support uprights 82 installed along the end sides 69 of the base 66 to which the brackets 70 are attached. According to an alternative embodiment (not shown) uprights 82 are supported by the base 66 directly and no pedestals 80 are used. The uprights 82 extend upwards from the base 66 when the base is in the operational position. The uprights 82 support photovoltaic cell modules 84 extending between the uprights installed on the opposed sides of the base 66. Each photovoltaic cell module 84 consists of a plurality of photovoltaic cells (not shown), installed with their active sides 86 facing the base 66.

The solar power submodule 65 also has concentrating reflectors on mirrors 88 extending horizontally in a plane drawn between the photovoltaic cell modules 84 and the base 66. In this position, the mirrors 88 will reflect the solar radiation to the active sides 86 of the photovoltaic cells. The mirrors 88 are supported by two support beams 90 attached to the uprights 82. The support beams 90 support ribs 92 to enhance stiffness of the mirrors 88.

The uprights 82 are preferably made hollow for using them as ducting for a coolant in a solar cell cooling system (not shown). This ducting is connected (not shown) to a condenser 94 attached to the underside of the base 66 by means of brackets (not shown). Alternatively, the condenser 94 can be attached to the underside of the base 66 by other means. The condenser is attached to a pump (not shown) that directs the coolant back to the photovoltaic cell modules 84. With this construction, the condenser 94, which is made as a coil, is positioned below the base 66, hence, below the pontoons 78 to be in the water body 44 (FIG. 6) for cooling.

The pontoons 78 (FIG. 12) have their ends 96, which connect to the adjacent pontoons 78, as shown in FIG. 8, where it can be seen how the solar power submodules 65 are arranged in solar power submodule rows 98 having solar power submodules 65 within each solar power submodule row 98 interconnected by means of the pontoons 78 secured in the openings 75 of the clamps 74 of the brackets 70 (FIG. 11). Referring again to FIG. 8, it can be seen also that adjacent pontoons 78 are arranged in pontoon rows 100. Since the brackets 70 have flexible portions 77 (FIG. 11), each solar power submodule 65 is capable of moving horizontally relative to the bracket 70 and turn with respect to the pontoon 78 under the action of waves in the water body 44 (FIG. 6).

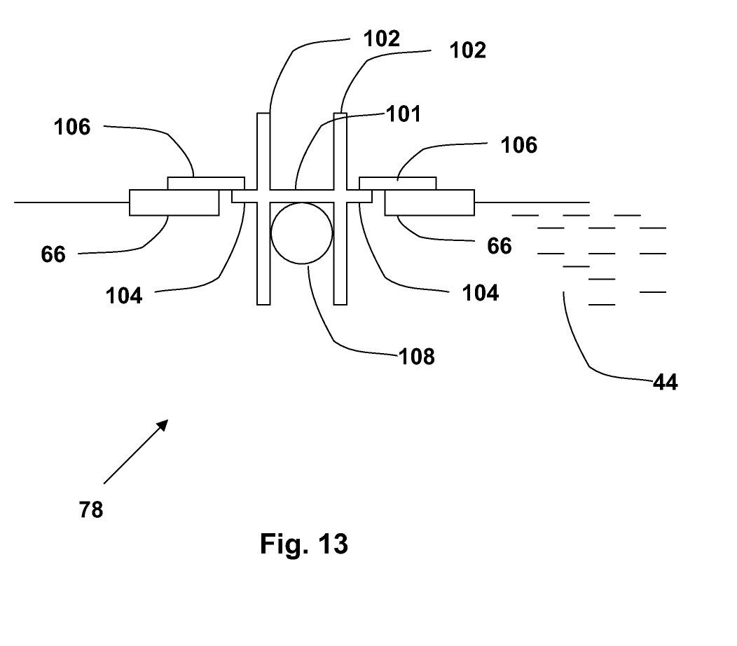

Another alternative embodiment of the pontoon 78 is shown in FIG. 13 where the pontoon 78 is built of an H-bar with a horizontal shelf 101 and two vertical side walls 102. Each side wall 102 has brackets 104 supporting flexible plates 106 secured to the brackets 104 by bolts (not shown). The flexible plates 106 support the bases 66 of the solar power modules 65 (not shown). The bases 66 of the solar power modules 65 (not shown) are secured to the flexible plates 106 by bolts (not shown).

The pontoon 78 is attached by clamps (not shown) to at least one flexible hollow pipe 108 sealed at both ends by plugs (not shown). The internal volume of each hollow pipe 108 is selected so that the buoyancy of the hollow pipe 108 is sufficient to ensure that the hollow pipe 108 with the pontoons 78 supporting the solar power modules 65 via the brackets 104 and the flexible plates 106 stay in floating position relative to the surface of the water body 44 (FIG. 6). According to one of available embodiments, the hollow pipe 108 is corrugated. Since the plates 106 are flexible, each solar power submodule 65 (see FIG. 8) is capable of turning with respect to the pontoon 78 under the action of waves in the water body 44.

Other constructions of solar power submodules 65 are available to those skilled in the art. With the construction shown in FIGS. 10, 11, 12, as well as an alternative construction schematically shown in FIG. 13, and with other available constructions, all solar power submodules 65 of each solar power submodule row 98 are located in substantially fixed positions relative to each other, each two adjacent rows 98 of the solar power submodules 65 will be movable relative to each other only in the direction of rotation around the pontoon row 100 positioned between these two rows 98 of the solar power submodules 65, and the pontoons rows 100 will be movable relative to each other only in the direction orthogonal to the direction of their axes.

The pontoon rows 100 are integrated in the circular frame 52 of the solar power module 48 by means of pre-tensioned flexible ties schematically shown at 63 in FIGS. 8 and 9.

It is understood that with the above-described design, all solar power submodules 65 are lined up in parallel, and all mirrors will reflect the solar radiation to all solar cells. In order to ensure that the mirrors are always facing in the direction of the sun, the circular frame 52 of each solar power module 48 (FIGS. 1, 8), which integrates the pontoon rows 98 supporting the rows 100 of the solar power submodules 65, should rotate synchronously with daily visible movement of the sun through the sky.

It is further understood that displacement in any horizontal direction of each circular frame 52 relative to the frame members 14, which form the cell 16 of the frame 12 (FIG. 1) surrounding the circular frame 52, under the force of wind and waves shall be restricted so that the circular frame 52 does not touch the frame members 14 of the surrounding cell 16 of the frame 12, therefore, preventing deformation of the circular frame 52 by impact of the frame members 14.

As shown schematically in FIGS. 14 and 15, for rotation of the circular frame 52 synchronously with daily visible movement of the sun through the sky, the circular frame 52 is secured to a driving pulley 110 by the driving belt 54 pre-tensioned by a tension device schematically shown as 112, and to a driving pulley 114 (shown in FIG. 15) by a driving belt 55 pre-tensioned by a tension device schematically shown as 116. The driving pulleys 54 and 55 are mounted on an output shaft 118 of a geared motor 120, which is mounted on a base 122 secured to the frame member 14 in the vicinity of one of the nodes 20 surrounding the cell 16 of the frame 12.

The driving belt 54 is engaged with the groove 60 (see FIG. 9) of the circular frame 52, wrapped around the circular frame 52 and secured to the outer surface of the outer wall 57 (see FIG. 9) of the circular frame 52 at a point 118. The driving belt 55 is engaged with the groove 60 (see FIG. 9) of the circular frame 52, wrapped around the circular frame 52 at an angular section, which is opposite to an angular section of the circular frame 52 engaged with the driving belt 54, and secured to the outer surface of the outer wall 57 (see FIG. 9) of the circular frame 52 at a point 120 located at such an angular coordinate that the driving belts 54 and 55 do not overlap to each other. According to another embodiment (not shown) both driving belts 54 and 55 are secured to the outer surface of the outer wall 57 (see FIG. 9) of the circular frame 52 at the point 120.

According to an alternative embodiment (not shown), the base 122 (see FIG. 15) is secured to the plate 22, which secures two frame members 14 to each other. According to another alternative embodiment (not shown), the base 122 is secured to both the plate 22 and the frame members 14 secured to each other. According to another alternative embodiment (not shown), the base 122 is secured to two frame members 14 secured to each other by the plate 22.

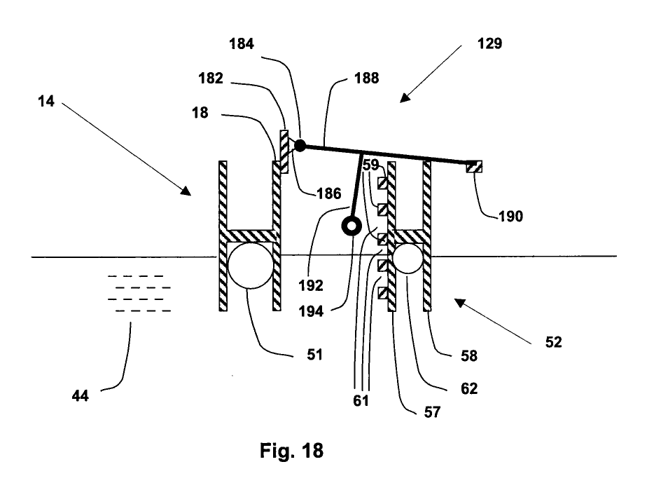

As shown schematically in FIG. 14, for restriction of displacement of the circular frame 52 in each horizontal direction, it is secured to the frame 12 by flexible ties 53, 124 and 126. One end of the flexible tie 53 is secured to the outer surface of the outer wall 57 (see FIG. 9) of the circular frame 52 at a point 128 located inside one of the grooves 61 (see FIG. 9), is engaged with the same groove of the grooves 61 (see FIG. 9), is wrapped around an angular part of the outer surface of the outer wall 57 (see FIG. 9) of the circular frame 52, passes through an eye (see FIG. 18) of the guiding mechanism shown schematically as 129, is wrapped around a roller 130, is wrapped around a roller 132, passes through an eye (see FIG. 18) of the guiding mechanism shown schematically as 133, is engaged with the same groove of the grooves 61 (see FIG. 9), is wrapped around another angular sector of the outer surface of the outer wall 57 (see FIG. 9) of the circular frame 52 and secured at the other end to the outer surface of the outer wall 57 (see FIG. 9) of the circular frame 52 at a point 134 located inside the same groove of the grooves 61 (see FIG. 9). According to another embodiment (not shown) both ends of the flexible tie 53 are secured to the outer surface of the outer wall 57 (see FIG. 9) of the circular frame 52 at the point 128.

One end of the flexible tie 124 is secured to the outer surface of the outer wall 57 (see FIG. 9) of the circular frame 52 at a point 136 located inside another groove of the grooves 61 (see FIG. 9), is engaged with the same groove of the grooves 61 (see FIG. 9) and wrapped around an angular part of the outer surface of the outer wall 57 (see FIG. 9) of the circular frame 52, passes through an eye (see FIG. 18) of the guiding mechanism shown schematically as 137, is wrapped around a roller 138, wrapped around a roller 140, passes through an eye (see FIG. 18) of the guiding mechanism shown schematically as 141, is engaged with the same groove of the grooves 61 (see FIG. 9), is wrapped around another angular sector of the outer surface of the outer wall 57 (see FIG. 9) of the circular frame 52 and is secured at the other end to the outer surface of the outer wall 57 (see FIG. 9) of the circular frame 52 at a point 142 located inside the same groove of the grooves 61 (see FIG. 9). According to another embodiment (not shown) both ends of the flexible tie 124 are secured to the outer surface of the outer wall 57 (see FIG. 9) of the circular frame 52 at the point 136.

One end of the flexible tie 126 is secured to the outer surface of the outer wall 57 (see FIG. 9) of the circular frame 52 at a point 144 located inside the third groove of the grooves 61 (see FIG. 9), is engaged with the same groove of the grooves 61 (see FIG. 9), is wrapped around an angular part of the outer surface of the outer wall 57 (see FIG. 9) of the circular frame 52, passes through an eye (see FIG. 18) of the guiding mechanism shown schematically as 145, is wrapped around a roller 146, is wrapped around a roller 148, passes through an eye (see FIG. 18) of the guiding mechanism shown schematically as 149, engaged with the same groove of the grooves 61 (see FIG. 9), wrapped around another angular part of the outer surface of the outer wall 57 (see FIG. 9) of the circular frame 52 and secured at the other end to the outer surface of the outer wall 57 (see FIG. 9) of the circular frame 52 at a point 150 located inside the same groove of the grooves 61 (see FIG. 9). According to another embodiment (not shown) both ends of the flexible tie 126 are secured to the outer surface of the outer wall 57 (see FIG. 9) of the circular frame 52 at the point 144.

According to an alternative embodiment (not shown), the flexible tie 53 is wrapped around the rollers 130 and 140, the flexible tie 124 is wrapped around the rollers 138 and 146, and the flexible tie 126 is wrapped around the rollers 132 and 148.

As shown in FIG. 14, the rollers 130, 132, 138, 140, and 148 are positioned substantially at the nodes of the frame 12, and the roller 146 is positioned along the respective frame member 14 of the frame 12 so that to avoid interference between the driving belts 54 and 55, on one side, and the flexible tie 126 and the roller 146, on the other side.

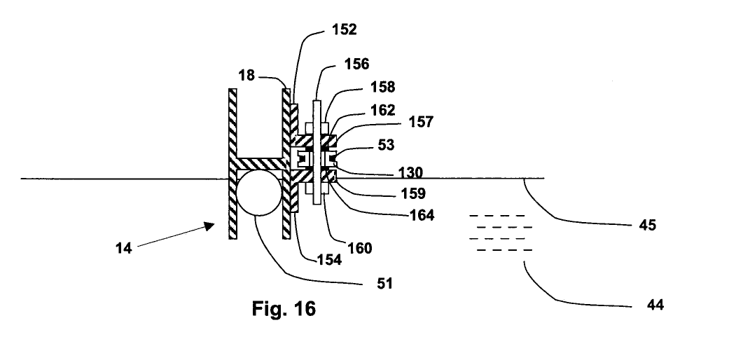

The details of a structure used to mount the roller 130 to the side wall 18 of the frame member 14 are shown in FIG. 16. Brackets 152 and 154, which are secured to the side wall 18 of the frame member 14 (supported at the surface 45 of the water body 44 by the hollow pipe 51) by bolts (not shown), support an axle 156 secured to a shelf 157 of the bracket 152 by a nut 158 and to a shelf 159 of the bracket 154 by a nut 160. The roller 130 with the flexible tie 53 wrapped around it is mounted at the axle 156 and is able to rotate freely about the axle 156 while movement of the roller 130 in the vertical direction is restricted by a washer 162 mounted at the axle 156 between the roller 130 and the shelf 157 of the bracket 152, and a washer 164 mounted at the axle 156 between the roller 130 and the shelf 159 of the bracket 154.

Other mechanisms identical to the mechanism shown in FIG. 16 are used to secure rollers 132, 138, 140, 146 and 148 to the respective frame members 14 of the frame 12.

The rotation mechanism shown in FIG. 14 supports rotation of the circular frame 52 clockwise or counterclockwise when observed from the top. More specifically, when the output shaft 118 of the geared motor 120 rotates in the clockwise direction when observed from the top, the pulleys 110 and 114 also rotate in the clockwise direction when observed from the top winding the driving belt 55 on the pulley 114 and unwinding the driving belt 54 from the pulley 110. The driving belt 55, being winded on the pulley 114, rotates the circular frame 52 clockwise when observed from the top. The tension mechanism 112 tensions the driving belt 54 preventing its entanglement with other components.

When the output shaft 118 of the geared motor 120 rotates in the counterclockwise direction when observed from the top, the pulleys 110 and 114 also rotate in the counterclockwise direction when observed from the top winding the driving belt 54 on the pulley 110 and unwinding the driving belt 55 from the pulley 114. The driving belt 54, being winded on the pulley 110, rotates the circular frame 52 counterclockwise when observed from the top. The tension mechanism 116 tensions the driving belt 55 preventing its entanglement with other components.

By selecting the clockwise (in the North hemisphere) or the counterclockwise (in the South hemisphere) direction of rotation of the output shaft 118 of the geared motor 120, the circular frame 52 can be rotated in the same direction with the output shaft 118 during the daytime in order to ensure that the mirrors 88 (see FIG. 10) are always facing in the direction of the sun. By selecting the counterclockwise (in the North hemisphere) or the clockwise (in the South hemisphere) direction of rotation of the output shaft 118 of the geared motor 120, the circular frame 52 can be rotated in the same direction with the output shaft 118 during the night time in order to return the circular frame 52 to a starting position for rotation on the next day.

As rollers 130, 132, 138, 140, 146 and 148 rotate freely about their respective axles 156 (FIG. 16), they do not create additional resistance to rotation of the circular frame 52 by allowing the flexible ties 53, 124 and 126 to rotate freely with the circular frame 52 and, at the same time, prevent displacement of the circular frame 52 in any horizontal direction by forces of wind and waves and, therefore, prevent any impact of the circular frame 52 against any frame member 14 of the cell 16 of the frame 12 surrounding the circular frame 52.

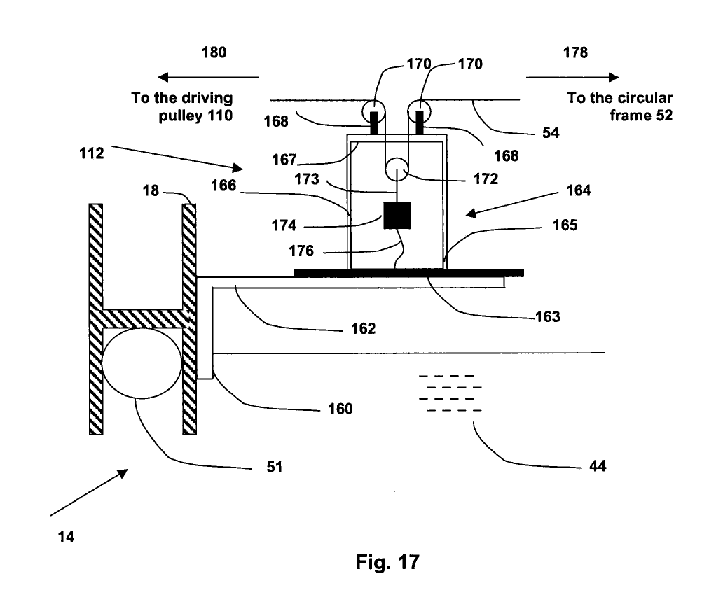

Details of the tension mechanism 112 are schematically shown in FIG. 17. The tension mechanism is supported by a shelf 162 of a bracket 160 secured to the wall 18 of the frame member 14 supported at the surface of the water body 44 by the hollow pipe 51. The shelf 162 supports a base 163, which supports a frame 164, which includes two legs 165 and 166 supporting the shelf 167. The shelf 167 supports four supports 168 (two of them are shown), which support two axles (not shown) that two pulleys 170 rotate about. The driving belt 54 is wrapped about each of the pulleys 170 and supports a pulley 172. The pulley 172 supports a flexible tie 173, which supports a load 174 secured to the base 163 by a flexible tie 176. When the driving belt 54 unwinds from the driving pulley 110, the load 174 tensions the driving belt 54 and prevents its entanglement with other components. The height of legs 165 and 166 is sufficiently large so that the load 174 do not touch the base 163 when the driving belt 54 unwinds from the driving pulley 110 (during rotation of the output shaft 118 of the geared motor 120 in the clockwise direction when viewed from the top) and is driven to a direction 178 by the circular frame 52 rotated clockwise when viewed from the top by the driving belt 55. The length of the flexible tie 176 is sufficiently short so that the pulley 172 never touches the shelf 166 when the flexible tie 176 is tensioned during rotation of the output shaft 118 of the geared motor 120 in the counterclockwise direction (when viewed from the top) when the driving belt 54 moves in a direction 180 toward the driving pulley 110 and winds on the driving pulley 110.

The tension mechanism 116 is substantially identical to the tension mechanism 112 according to one embodiment.

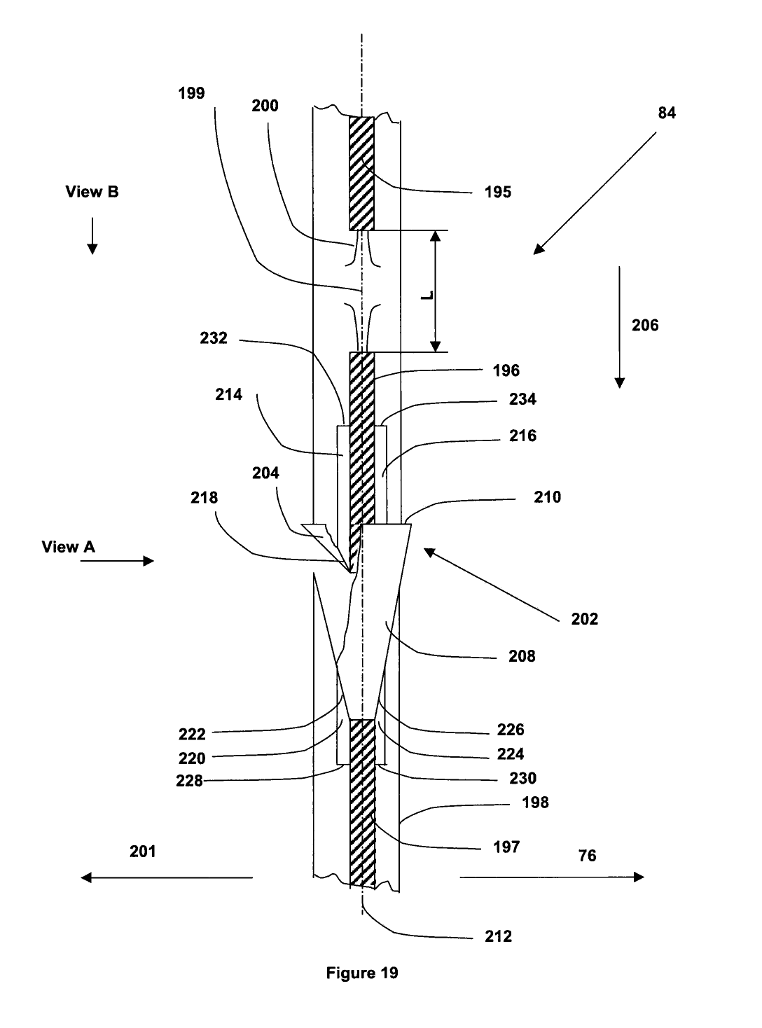

Details of the guiding mechanism 129 are shown in FIGS. 18 and 19. A base plate 182 is secured by bolts (not shown) to the wall 18 of the frame member 14 supported at the surface of the water body 44 by the hollow pipe 51. A hinge 184 is secured to the base plate 182 by a support 186. A rod 188 is supported at one end by the hinge 184 and rotates freely about this hinge. The rod 188 is pressed, at the other end, which is opposite to the hinge 184, by a load 190 against the inner side wall 58 of the circular frame 52 supported at the surface of the water body 44 by the hollow pipe 62. A tie 192 is rigidly secured to the rod 188 and supports an eye 194 located at the end of the tie 192, which is opposite to the rod 188. The length of the tie 192 is selected so that the eye 194 stays substantially at the same level with the top groove of the three grooves 61 formed by the rings 59 attached to the outer surface of the outer wall 57 of the circular frame 52. When the circular frame 52 rotates about the vertical axis, it slides by the rod 188, which stays substantially at the same position and supports the eye 194 via the tie 192 at substantially the same position regardless the angular position of the circular frame rotating about its vertical axis. The flexible tie 53 (see FIG. 14) passes through the eye 194 and engages with the top groove of the three grooves 61 formed by the rings 59 attached to the outer surface of the outer wall 57 of the circular frame 52. Alternative embodiments of the guiding mechanism are available to those skilled in art.

Referring now to FIG. 19, details of the structure of the bottom 238 (FIG. 21) of the photovoltaic cell module 84 (see FIG. 10) are shown according to an exemplary embodiment. Photovoltaic cells 195, 196, 197 and the other photovoltaic cells (not shown) of the photovoltaic cell module 84 (see FIG. 10) are secured to the bottom of an evaporative cooling chamber 198 described in PCT/US2009/048279 (the disclosure of which is hereby incorporated by reference in its entirety) in a row at a certain distance L between each other. An area 199 of the bottom of the evaporative cooling chamber 198 located between two adjacent photovoltaic cells 196 and 197 is used for positioning electrical cables 200 coming to the photovoltaic cells 195 and 196 (not shown). The photovoltaic cells 195, 196, 197 and the other photovoltaic cells (not shown) of the photovoltaic cell module 84 are in heat-removal relationship with the evaporative cooling chamber 198. However, electrical cables 200 coming to the photovoltaic cells 195, 196, 197 and the other photovoltaic cells (not shown) of the photovoltaic cell module 84 are not in heat-removal relationship with the evaporative cooling chamber 198 and, therefore, should be protected against irradiation by sunlight focused by mirrors 88 (see FIG. 10) at the axial part of the bottom of the evaporative cooling chamber 198.

Furthermore, the solar power submodule 65 (see FIG. 10) can rotate about the horizontal line orthogonal to the line 76 under the force of waves. As a result of this rotation, sunlight directed by the mirrors 88 to the photovoltaic cells 195, 196, 197 and the other photovoltaic cells (not shown) of the photovoltaic cell module 84 can miss these photovoltaic cells by being shifted in the lateral direction 76 or in the opposite lateral direction 201.

Both problems with protection of the area 199 against irradiation of focused sunlight and re-focusing to the photovoltaic cells 195, 196, 197 and the other photovoltaic cells (not shown) of the photovoltaic cell module 84 of focused sunlight displaced in the lateral directions 76 or 201 as a result of rotation of the solar power submodule 65 (see FIG. 10) about the horizontal line orthogonal to the lines 76 and 201 by waves can be solved by securing mirror structures 202 to the bottom of the evaporative cooling chamber 198 as shown in FIG. 19. The mirror structure 202 should be maintained below each area 199 of the bottom of the evaporative cooling chamber 198 located between two adjacent photovoltaic cells 195 and 196, 196 and 197, etc. However, the mirror structure 202 installed below the area 199 of the bottom of the evaporative cooling chamber 198 located between the adjacent photovoltaic cells 195 and 196 is not shown in FIG. 19.

The mirror structure 202 consists of the following six substantially planar mirrors joined to each other: a front lateral mirror 204 oriented by its reflecting surface toward the direction 206 of incident sunlight; a back lateral mirror 208 oriented by its reflecting surface in the direction opposite to the direction 206 of incident sunlight and joined to the front lateral mirror 204 at a horizontal intersection line 210, which is orthogonal to the longitudinal axis 212 of the evaporation chamber 198; a front left side mirror 214 joined to the front lateral mirror 204 along a line 218; a front right side mirror 216 joined to the front lateral mirror 204 along a line (not shown), which is symmetrical to the line 218 relative to a plain cut through the axis 212 orthogonally to the plain of FIG. 19; a back left side mirror 220 joined to the back lateral mirror 208 along a line 222; and a back right side mirror 224 joined to the back lateral mirror 208 along a line 226. The front left side mirror 214 and the back left side mirror 220 have substantially identical cross-sections orthogonal to the axis. The front right side mirror 216 and the back right side mirror 224 have substantially identical cross-sections orthogonal to the axis also. Furthermore, the front left side mirror 214 is substantially symmetrical to the front right side mirror 216 and the back left side mirror 220 is substantially symmetrical to the back right side mirror 224 relative to the plain cut through the axis 212 orthogonally to the plain of FIG. 19.

Mirror structures 202 are installed in a row along the entire row of the photovoltaic cells 195, 196, 197, etc. so that a front end 232 of the front left side mirror 214 and a front end 234 of the front right side mirror 216 of the mirror structure 202 are joined, respectively, to the back ends 228 of the back left side mirror 220 and 230 of the back right side mirror 230 of another mirror structure 202 (not shown), which is installed below the area 199 located between the photovoltaic cells 195 and 196. Other adjacent mirror structures 202 are joined to each other in the same fashion and form a continuous row of mirror structures 202 along the entire row of the photovoltaic cells 195, 196, 197, etc.

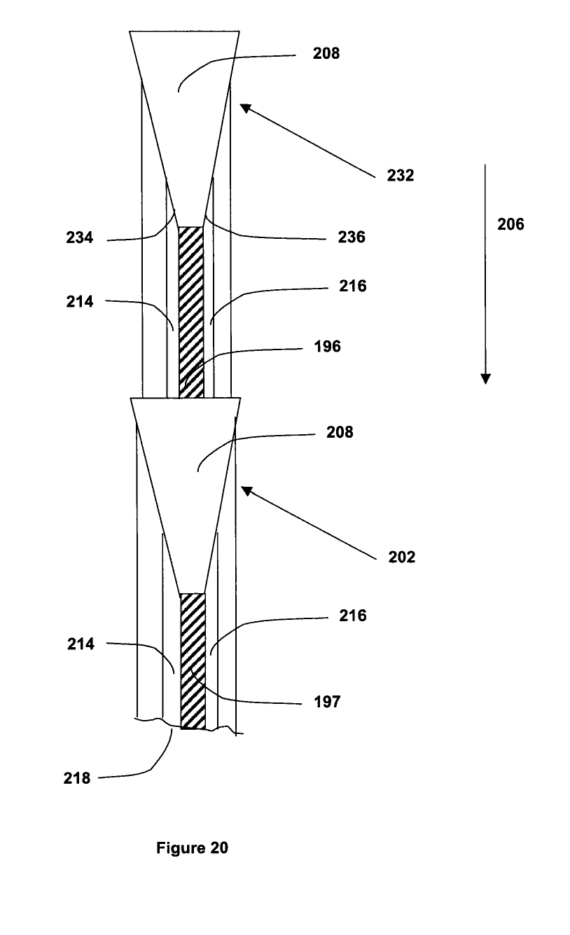

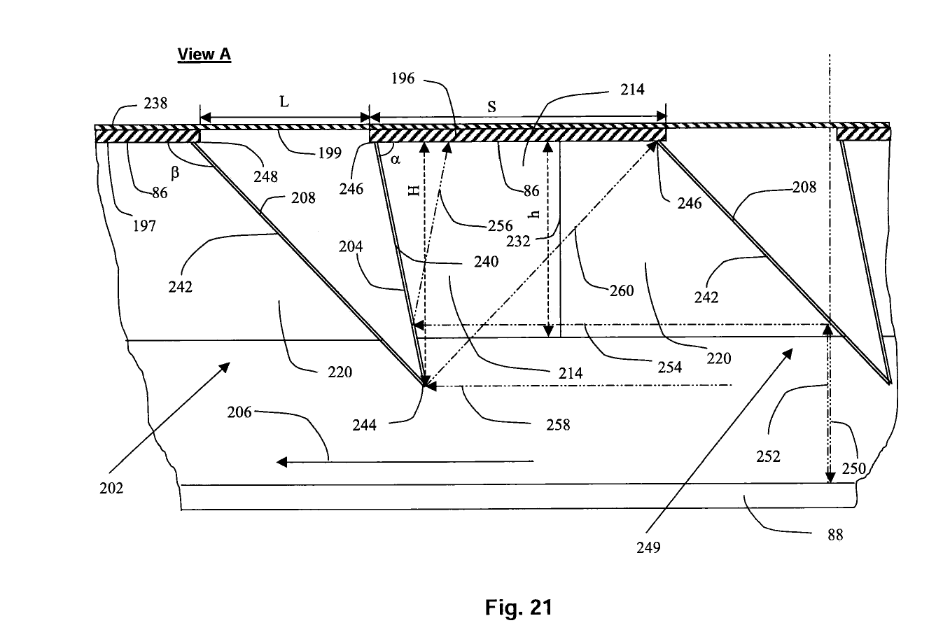

According to an alternative embodiment shown in FIG. 20, the mirror structure 202 consists of the front lateral mirror (not shown), the back lateral mirror 208 and two front side mirrors 214 and 216. According to this embodiment, the mirror structure 202 has no back side mirrors. The front side mirrors 214 and 216 of the mirror structure 202 join the back mirror 208 of the adjacent mirror structure 232 along lines 234 and 236.

According to another alternative embodiment (not shown), the mirror structure consists of the front and back lateral mirrors and two back side mirrors, and has no front side mirrors. According to this embodiment, the end side mirrors of each mirror structure join the front lateral mirror of the mirror structure, which stays behind the first mirror structure along the direction of incident sunlight.

According to another alternative embodiment, the entire row of mirror structures 202 can be fabricated of a single sheet of material by stamping and, then, covered with mirror film. Regardless the method of fabrication and composition of mirror structures 202, members of a row of mirror structures 202 surround each photovoltaic cell 195, 196, 197, etc. of the row of photovoltaic cells.

Details of the front lateral mirror 204 and the back lateral mirror 208 of FIG. 19 are schematically shown in FIG. 21 where the side view A of FIG. 19 is rendered. The substantially planar front lateral mirror 204 is inclined at an acute angle α to the active side 86 of the photovoltaic cell 196 mounted at the bottom 238 of the evaporative cooling chamber 198. A reflecting surface 240 of the front lateral mirror 204 is oriented toward the direction 206 of incident sunlight. The substantially planar back lateral mirror 208 is inclined at an obtuse angle β to the active side 86 of the photovoltaic cell 197 mounted at the bottom 238 of the evaporative cooling chamber 198. A reflecting surface 242 of the back lateral mirror 208 is oriented toward a direction opposite to the direction 206 of incident sunlight. The front lateral mirror 204 and the back lateral mirror 208 join along the horizontal intersection line 210 (see FIG. 19), which crosses the plane shown in FIG. 21 at an apex point 244 located at a distance H below the active side 86 of the photovoltaic cell 196. The top end 246 of the front lateral mirror 204 opposite to the apex 244 is located substantially next to the back (when viewing along the direction 206) end of the photovoltaic cell 196 and is shifted off the back end of the photovoltaic cell 196 toward the center of the photovoltaic cell 196. The top end 248 of the back lateral mirror 208 opposite to the apex 244 is located substantially at the front (when viewing along the direction 206) end of the photovoltaic cell 197 and is also shifted off the front end of the photovoltaic cell 197 toward the center of the photovoltaic cell 197. This configuration provides complete protection of the area 199 of the bottom 238 of the evaporative cooling chamber 198 used to position cables 200 (see FIG. 19) against sunlight focused there by mirrors 88. The length of this area in the direction 206 is L.

The left front side mirror 214 of the mirror structure 202 is joined with the back front side mirror 220 of the adjacent mirror structure 249 along the line 232. The height, h, of the side mirrors 214 and 240 shown in FIG. 21 is smaller than the distance H between the active surface 86 of the photovoltaic cell 196 and the apex point 244. According to an alternative embodiment (not shown), the height, h, is larger than the distance H. According to another alternative embodiment (not shown), the height, h, is equal to the distance H.

In order to focus substantially all sunlight reflected by the mirror 88 at the active surface 86 of the photovoltaic cell 196, the angles α and β shall be selected within certain ranges.

We discuss now the two least favorable trajectories of incident sunrays.

When the sun reaches zenith, a sunray 250 incident to the mirror 88 is directed vertically downward and, then, reflected from the mirror as a sunray 252 directed vertically upward. Then, it is reflected from the reflecting surface 242 of the back lateral mirror 208 as a sunray 254, which is, in turn reflected from the reflecting surface 240 of the front lateral mirror 204 as a sunray 256. In order for the sunray 256 to be incident to the active surface 86 of the photovoltaic cell 196, the following condition shall be met:

β<180°−α/2 (1)

If this condition is not met, the sunray 256 will be reflected from the reflecting surface 240 of the front lateral mirror 204 toward the mirror 88 and will typically not reach the active surface 86 of the photovoltaic cell 196.

The opposite unfavorable situation occurs when the sun is very low above the horizon and incident sunrays are substantially horizontal. The horizontal sunray incident to the apex point 244 is shown as 258 in FIG. 21. A configuration is shown in FIG. 21 where the sunray 258 reflected from the reflecting surface 240 of the front lateral mirror 204 at the apex point 244 is incident to the point 246 where the active surface 86 of the photovoltaic cell 196 reaches the back mirror 208 of the adjacent mirror structure 249.

This configuration is, indeed, optimal. If the sunray 258 after being reflected from the reflecting surface 240 of the front lateral mirror 204 at the apex point 244 turns clockwise off the line 260, it would be incident to the reflecting surface 242 of the back lateral mirror 208 of the adjacent mirror structure 249 and, then, reflected toward the mirror 88 and away from the active surface 86 of the photovoltaic cell 196. Alternatively, if the sunray 258 after being reflected from the reflecting surface 240 of the front lateral mirror 204 of the mirror structure 202 at the apex point 244 turns counterclockwise off the line 260, this configuration is characterized by lower than optimal distance H between the active surface 86 of the photovoltaic cell 196 and the apex point 244 of the mirror structure 202 and, respectively, by lower than optimal length L of the area 199 at any given value of the angle β, while achieving an optimal length L improves the design significantly as it allows for better installation of cables 200 (FIG. 19), longer service life of these cable and increase in overall serviceability of the solar power plant.

Furthermore, for the configuration shown in FIG. 21 where the sunray 258 reflected from the reflecting surface 240 of the front lateral mirror 204 of the mirror structure 202 at the apex point 244 is incident to the point 246 where the active surface 86 of the photovoltaic cell 196 reaches the back mirror 208 of the adjacent mirror structure 249, there is an optimal range of values of angle α, which allows to achieve the maximum ratio of the length L of the area 199 to the length S of the photovoltaic cell 86 in the direction 206 of incident sunlight at any given value of the angle β.

Selection of a value of the acute angle α in the range of 60° to 80° and a value of the obtuse angle β in the range of 125° to 145° and meeting the condition (1) ensures that the mirror structure 202 shown in FIG. 21 focuses the most unfavorable incident sunrays 250 and 258 at the active surface 86 of the photovoltaic cell 196. Therefore, such a system focuses any incident sunray coming from the direction 206 at the active surface 86 of the photovoltaic cell 196.

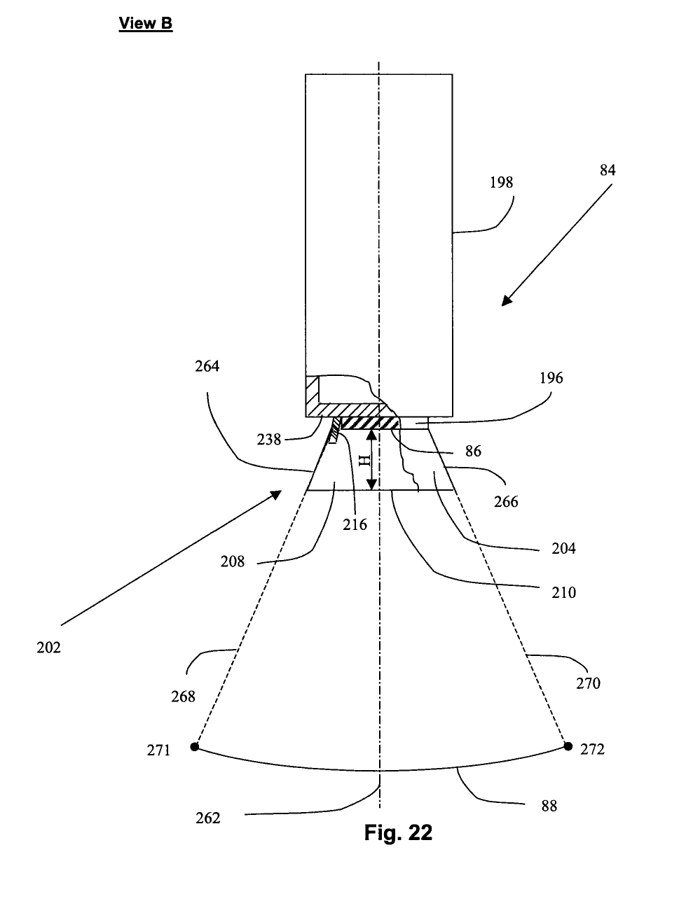

A front view B (see FIG. 19) of the mirror structure 202 is schematically shown in FIG. 22. It is shown that both the front lateral mirror 204 and the back lateral mirror 208 have a trapezoid form with a width of the top of each trapezoid in the direction orthogonal to the vertical axis of symmetry 262 corresponding to the width in the same direction of the photovoltaic cell 196 secured to the bottom 238 of the evaporative cooling chamber 198 of the photovoltaic cell module 84. Both the front lateral mirror 204 and the back lateral mirror 208 are substantially symmetric relative to the vertical axis of symmetry 262 and both sides of each trapezoid projected into the plane of FIG. 22 as 264 and 266 are oriented so that respective projections of a continuation 268 of the line 264 and a continuation 270 of the line 266 into the plane of FIG. 22 pass through the points 271 and 272 respectively, which are projections of the edges of the mirror 88 into the plane of FIG. 22. Such orientation of the sides 264 and 266 of the front lateral mirror 204 and the back lateral mirror 208 ensures that the respective area 199 (see FIG. 19) of the bottom 238 of the evaporative cooling chamber 198 of the photovoltaic cell module 84 located between two adjacent photovoltaic cells 195 and 196 (see FIG. 19) is protected against undesirable sunlight focused there by the mirror 88.

As the distance H between the active surface 86 of the photovoltaic cell 196 and the horizontal intersection line 210 where the back lateral mirror 208 joins the front lateral mirror 204 is determined for the best configuration shown in FIG. 21 by the length S of the photovoltaic cell 196 and the angle α between the front lateral mirror 204 and the photovoltaic cell 196 (see FIG. 21), the orientation of the sides 264 and 266 of the back lateral mirror 208 and the front lateral mirror 204 shown in FIG. 22 determines the geometry of these lateral mirrors for any selected combination of the length S of the photovoltaic cell 196, the acute angle α between the front lateral mirror 204 and the photovoltaic cell 196 and the obtuse angle β between the back lateral mirror 208 and the photovoltaic cell 196.

As shown in FIG. 22, the front side mirror 216 is located at a smaller angle to the axis 262 than the sides 264 and 266 of the lateral mirrors 204 and 208.

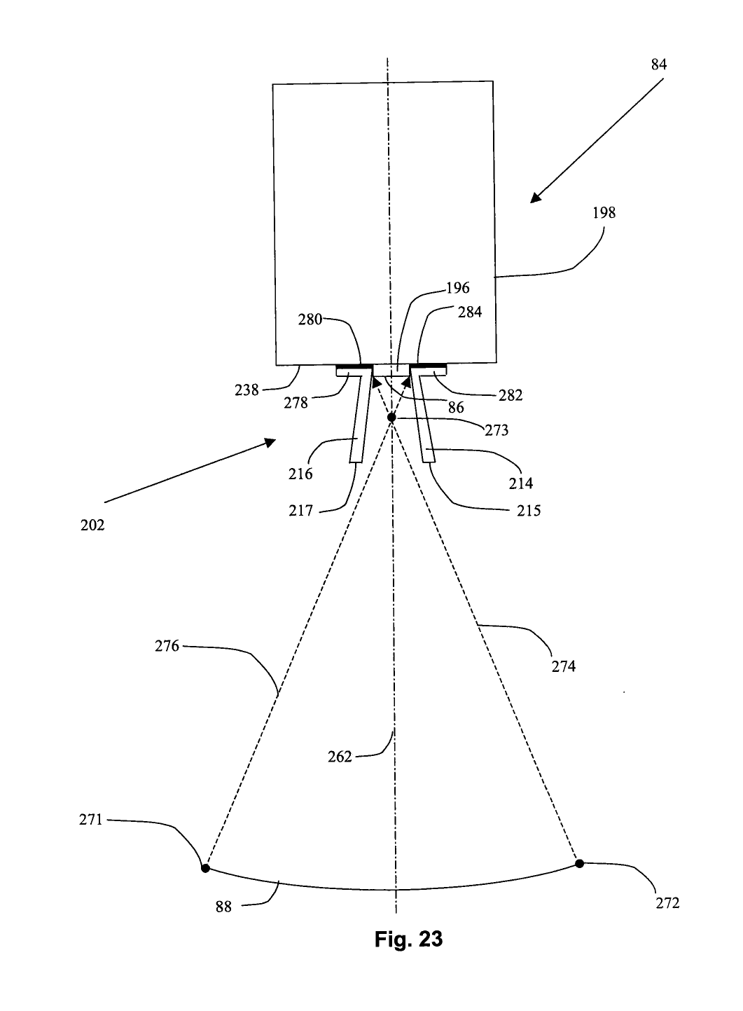

A front view of the front side mirrors 214 and 216 is schematically shown in FIG. 23 where the front and back lateral mirrors are not shown. As shown in FIG. 23, a focus 273 of the mirror 88 is located below the active surface 86 of the photovoltaic cell 196 secured to the bottom 238 of the evaporative cooling chamber 198 of the photovoltaic cell module 84 at such a distance that the sunray 274 reflected from the mirror 88 at its end point 272 is incident to the active surface 86 of the photovoltaic cell 196 substantially at its end point located at the opposite side of the symmetry line 262 from the point 272 and the sunray 276 reflected from the mirror 88 at the other end point 271 is incident to the active surface 86 of the photovoltaic cell 196 substantially at its end point located at the opposite side of the symmetry line 262 from the point 271.

Each of the side mirrors 214 and 216 is inclined outward at a small angle to the vertical direction, and the length of each mirror is selected so that the low end 215 of the mirror 214 is located below the focus 273 and does not touch the line 274, and the low end 217 of the mirror 216 is located below the focus 273 and does not touch the line 276. The distance between the high ends of the side mirrors 214 and 216 is determined by the width of the photovoltaic cell 196. The configuration of the side mirrors 214 and 216 shown in FIG. 23 ensures robustness of the optical characteristics against rotation of the solar power submodule 65 (see FIG. 10) about a horizontal line orthogonal to the plane of FIG. 23 under the force of waves.

The side mirror 216 is secured to the bottom 238 of the evaporative cooling chamber 198 of the photovoltaic cell module 84 by a base 278 via an adhesive layer 280. The side mirror 214 is secured to the bottom 238 of the evaporative cooling chamber 198 of the photovoltaic cell module 84 by a base 282 via an adhesive layer 284.

The cross-section of the end side mirror 220 is identical to the cross-section of the front side mirror 214, and the cross-section of the end side mirror 224 is identical to the cross-section of the front side mirror 216. The bases of the side mirrors 220 and 224 (not shown) are secured to the bottom 238 of the evaporative cooling chamber 198 by adhesive layers (not shown) identical to adhesive layers 278 and 282.

As utilized herein, the terms “approximately,” “about,” “substantially,” and similar terms are intended to have a broad meaning in harmony with the common and accepted usage by those of ordinary skill in the art to which the subject matter of this disclosure pertains. It should be understood by those of skill in the art who review this disclosure that these terms are intended to allow a description of certain features described and claimed without restricting the scope of these features to the precise numerical ranges provided. Accordingly, these terms should be interpreted as indicating that insubstantial or inconsequential modifications or alterations of the subject matter described and claimed are considered to be within the scope of the invention as recited in the appended claims.

It should be noted that the term “exemplary” as used herein to describe various embodiments is intended to indicate that such embodiments are possible examples, representations, and/or illustrations of possible embodiments (and such term is not intended to connote that such embodiments are necessarily extraordinary or superlative examples).

The terms “coupled,” “connected,” and the like as used herein mean the joining of two members directly or indirectly to one another. Such joining may be stationary (e.g., permanent) or moveable (e.g., removable or releasable). Such joining may be achieved with the two members or the two members and any additional intermediate members being integrally formed as a single unitary body with one another or with the two members or the two members and any additional intermediate members being attached to one another.

It should be noted that the orientation of various elements may differ according to other exemplary embodiments, and that such variations are intended to be encompassed by the present disclosure.

It is also important to note that the construction and arrangement of the systems and description of methods for the floating solar power plant as shown in the various exemplary embodiments is illustrative only. Although only a few embodiments of the present inventions have been described in detail in this disclosure, those skilled in the art who review this disclosure will readily appreciate that many modifications are possible without materially departing from the novel teachings and advantages of the subject matter disclosed herein. Accordingly, all such modifications are intended to be included within the scope of the present invention as defined in the appended claims. The order or sequence of any process or method steps may be varied or re-sequenced according to alternative embodiments. Other substitutions, modifications, changes and omissions may be made in the design, operating conditions and arrangement of the various exemplary embodiments without departing from the scope of the present inventions.

What is claimed is:

1. A floating solar power plant, comprising: a frame floating at the surface of a water body, where the frame includes at least one cell, which is secured by at least one flexible tie to at least one floating support, which is secured to a shore of the water body by at least one suspension, with the length of each suspension selected so that the floating supports remain at the surface of the water body under all conditions of seasonal variation of water level in the water body.

2. The solar power plant of claim 1 wherein the size of the frame and the lengths of the flexible ties and suspensions are selected so that when at least one flexible tie and at least one suspension located at any side of the frame, as well as at least one flexible tie located at the opposite side of the frame are tensioned, all supports located at this opposite side of the frame remain within the perimeter of the water body.

3. The solar power plant of claim 2 wherein at least one cell of the frame comprises at least one solar power module, which comprises:
a circular frame and at least two rows of pontoons and each end of each row of pontoons secured to the circular frame by at least two pre-tensioned flexible ties oriented in substantially radial directions; and
at least one solar power submodule secured to two adjacent rows of pontoons where all solar power submodules, which form a row of solar power submodules being secured to the same two rows of pontoons, are located in substantially fixed positions relative to each other; each two adjacent rows of the solar power submodules are movable relative to each other only in the direction of rotation about the pontoon row positioned between these two rows of the solar power submodules; and the pontoons rows are movable relative to each other only in the direction orthogonal to the direction of their axes.

4. The solar power plant of claim 3 wherein at least one frame member is built as a substantially rigid structure secured to at least one hollow sealed pipe supporting it in floating position relative to the surface of the water body.

5. The solar power plant of claim 3 wherein the circular frame is built as a substantially rigid structure secured to at least one hollow sealed pipe supporting it in floating position relative to the surface of the water body.

6. The solar power plant of claim 3 wherein at least one pontoon is built as a substantially rigid structure secured to at least one hollow sealed pipe supporting it in floating position relative to the surface of the water body.

7. The solar power plant of claim 4 wherein the circular frame is secured against displacement in the horizontal directions by three flexible ties, each of the ties is wrapped around the circular frame and two rollers that rotate freely around vertical axles installed substantially at two different nodes of the cell of the frame surrounding the circular frame.

8. The solar power station of claim 7 wherein at least one part of the evaporator bottom located between two adjacent solar panels is covered with a downward-oriented mirror structure that includes two lateral mirrors having a horizontal line of intersection and positioned at such angles to the evaporator bottom that the reflecting surface of each mirror is oriented toward the solar panel adjacent to this lateral mirror, the reflecting surface of one lateral mirror is oriented in the direction of the sun, and the reflecting surface of the other lateral mirror is oriented in the direction opposite to the sun.

9. The solar power station of claim 8 wherein the edge of at least one lateral mirror opposite to the line of their intersection is located substantially close to the end of the respective solar element and covers the part of the evaporator bottom located above this lateral mirror and between the two solar elements adjacent to this part.

10. The solar power station of claim 9 wherein at least one lateral mirror with the reflecting surface oriented in the direction of the sun is inclined at an acute angle α within a range of approximately 60° to 80° to the evaporator bottom and the vertical distance between the bottom of the evaporator and the horizontal line of intersection of this lateral mirror with a respective lateral mirror with the reflecting surface oriented in the direction opposite the sun is selected so that the horizontal sunray incident to the lateral mirror with the reflecting surface oriented in the direction of the sun substantially close to the line of intersection of both lateral mirrors is reflected substantially to the end of the solar element opposite to this mirror.

11. The solar power station of claim 10 wherein at least one lateral mirror with the reflecting surface oriented in the direction opposite to the sun is inclined at an obtuse angle β within a range of approximately 125° to 145° to the evaporator bottom, and this angle β is less than the difference between 180° and a half of the angle α of claim 8.

12. The solar power station of claim 11 wherein at least one lateral mirror has a form of a trapezoid with at least one side oriented so that the continuation of this side passes through the end of a concentrating reflector.

13. The solar power station of claim 12 wherein the focus of the concentrating reflector of the solar power submodule is located below an active surface of at least one photovoltaic cell and a straight line connecting at least one end of the concentrating reflector of the solar power submodule with the focus of this concentrating reflector continues substantially through the end of the photovoltaic cell located at the other side of the vertical symmetry line from this end of the concentrating reflector.

14. The solar power station of claim 13 wherein the downward-oriented mirror structure includes at least one side mirror wherein the low end of the said side mirror is located above at least one straight line connecting one end of the concentrating reflector with the focus of the said concentrating reflector.

15. A scalable floating solar power plant for use in a water body, comprising:
a frame comprising a plurality of frame members defining a plurality of geometric cells arranged in a formation so that each pair of adjacent cells has a shared node;
the geometric cells each including a solar power module having a circular frame that is rotatably coupled to its respective geometric cell; and
a plurality of buoyant supports coupled to the frame by a flexible tie, and having a flexible suspension configured for coupling to a bolster.

16. The scalable floating solar power plant of claim 15 further comprising at least one roller, a drive belt and a tensioning mechanism coupled to a frame member and configured to rotate the solar power module relative to the frame.

17. The scalable floating solar power plant of claim 15 wherein the solar power modules each comprise a plurality of solar power submodules, the solar power submodules each comprising a base, at least one photovoltaic cell module supported above the base and facing toward the base, and a concentrating reflector disposed between the photovoltaic cell module and the base and configured to focus sunlight on the photovoltaic module.

18. The scalable floating solar power plant of claim 17, wherein at least one solar power submodule further comprises a condenser coupled to an underside of the base and configured to receive a coolant circulating in communication with the photovoltaic cell module and to be cooled by the water body.

19. The scalable floating solar power plant of claim 18 wherein the solar power submodules further comprise flexible brackets, wherein the flexible brackets receive pontoons extending along opposite sides of the base and transverse to the orientation of the photovoltaic cell modules.

20. The scalable floating solar power plant of claim 19 wherein the solar power submodules are linked to one another at least in part by the pontoons and are movable about an axis of the pontoons.

21. The scalable floating solar power plant of claim 20 wherein the solar power submodules are linked to the circular frame of the solar power module by the pontoons.

22. The scalable floating solar power plant of claim 15 wherein the geometric cells are arranged in a staggered formation so that each pair of adjacent cells has a shared node and no shared frame members.

23. The scalable floating solar power plant of claim 15 wherein the circular frame of the solar power module comprises an H-shaped member, and a sealed hollow pipe disposed in a lower portion of the H-shaped member.
